(19) United States
(12) Patent Application Publication
(10) Pub. No.: US 2012/0329256 A1
(43) Pub. Date: Dec. 27, 2012

(54) METHOD OF MANUFACTURING SEMICONDUCTOR DEVICE AND ION IMPLANTER

(75) Inventors: Takayuki ITO, Mie (JP); Koji Hadano, Oita (JP); Masayuki Jinguji, Oita (JP)

(73) Assignee: Kabushiki Kaisha Toshiba, Tokyo (JP)

(21) Appl. No.: 13/416,679

(22) Filed: Mar. 9, 2012

(30) Foreign Application Priority Data
Jun. 22, 2011 (JP) 2011-138658

(51) Int. Cl. H01L 21/265

(52) U.S. Cl. 438/514; 250/492.21; 257/E21.334

(57) ABSTRACT

According to an embodiment, a method of manufacturing a semiconductor device is provided. This method of manufacturing a semiconductor device sets a first voltage to be applied to an electrode configured to extract an ion beam from an ion source, and a second voltage to be applied to a decelerator through which an ion beam extracted from the ion source is to pass, on the basis of a second impurity profile which is formed in a substrate by neutral particles included in the ion beam.

### CROSS-REFERENCE TO RELATED APPLICATIONS

This application is based upon and claims the benefit of priority from Japanese Patent Application No. 2011-138658, filed on Jun. 22, 2011; the entire contents of which are incorporated herein by reference.

### FIELD

Embodiments described herein relate generally to a method of manufacturing a semiconductor device and an ion implanter.

### BACKGROUND

Conventionally, there has been known a method of manufacturing a semiconductor device which forms an impurity diffused layer through a plurality of times of ion implantation. For example, there has been known a technology which forms an impurity diffused layer by separately performing high dose ion implantation with low acceleration energy and low dose ion implantation with high acceleration energy.

However, in the method of manufacturing a semiconductor device, there is a problem in which an increase in the number of times of ion implantation decreases throughput.

### BRIEF DESCRIPTION OF THE DRAWINGS

FIGS. 1A and 1B are explanatory diagrams illustrating a manufacturing method according to a first embodiment;

FIG. 2 is a diagram illustrating the configuration of a semiconductor device according to the first embodiment;

FIG. 3 is a diagram illustrating the configuration of an ion implanter for performing the manufacturing method according to the first embodiment;

FIG. 4 is a diagram illustrating the procedure of the manufacturing method according to the first embodiment;

FIG. 5 is a diagram illustrating impurity profiles which are formed in the semiconductor device according to the first embodiment;

FIG. 6 is a cross-sectional view for describing a process of the method of manufacturing a semiconductor device according to the first embodiment;

FIGS. 7A, 7B, 8A, and 8B are explanatory diagrams illustrating occurrence of residual defects;

FIGS. 9A, 9B, 10A, and 10B are explanatory diagrams illustrating a manufacturing method according to a second embodiment;

FIG. 11 is a cross-sectional view illustrating a semiconductor device according to a third embodiment;

FIG. 12 is an explanatory diagram illustrating a procedure of a manufacturing method according to the third embodiment; and

FIGS. 13 to 15 are cross-sectional views for describing processes of the manufacturing method according to the third embodiment.

### DETAILED DESCRIPTION

According to an embodiment, a method of manufacturing a semiconductor device is provided. The method of manufacturing a semiconductor device includes: applying a first voltage to an electrode configured to extract an ion beam from an ion source, thereby extracting an ion beam from the ion source; applying a second voltage to a decelerator through which the extracted ion beam is to pass, thereby reducing acceleration energy of the ion beam; irradiating the ion beam having passed through the decelerator onto a substrate, thereby forming a first impurity profile based on ions included in the ion beam and a second impurity profile based on neutral particles included in the ion beam, in the substrate; and setting the first voltage and the second voltage in accordance with the second impurity profile.

Hereinafter, methods of manufacturing a semiconductor device and ion implanters according to embodiments will be described in detail with reference to the accompanying drawings. However, the present invention is not limited to the embodiments. Hereinafter, a method of manufacturing a semiconductor device is simply referred to as a “manufacturing method”.

### First Embodiment

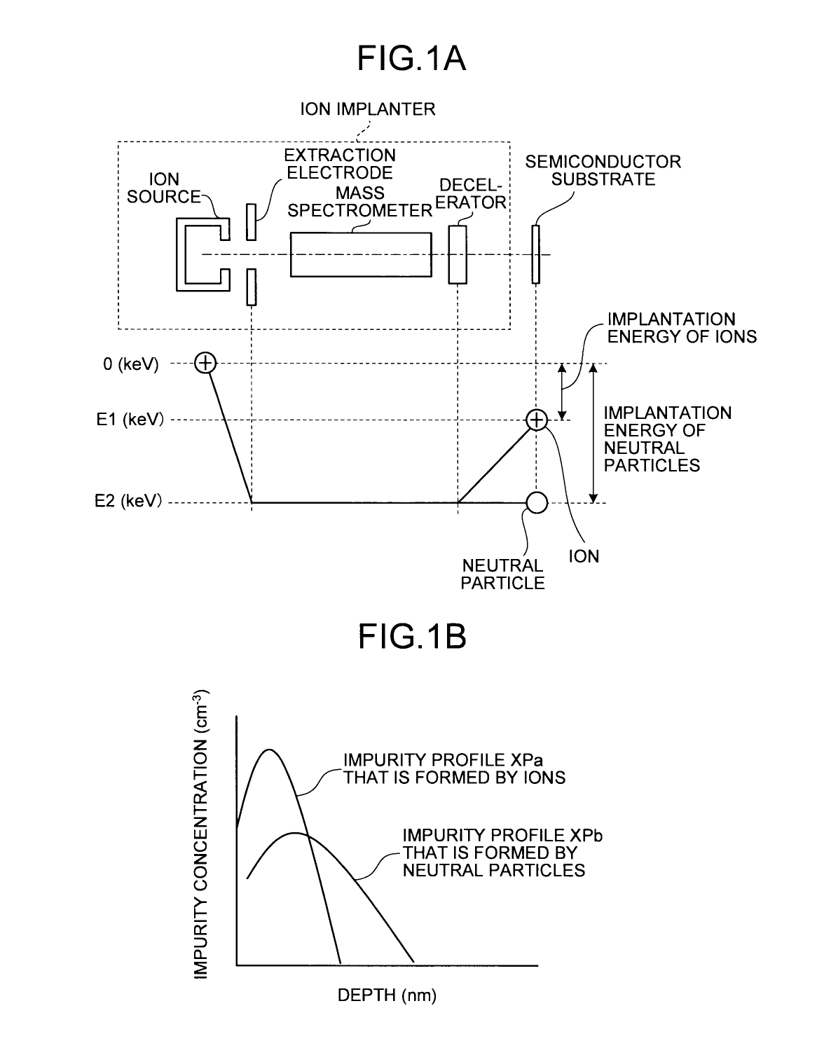

First, a manufacturing method according to a first embodiment will be described with reference to FIGS. 1A and 1B. FIGS. 1A and 1B are explanatory diagrams illustrating the manufacturing method according to the first embodiment.

The manufacturing method according to the first embodiment includes a process of converting a material to be an impurity into ions and implanting the ions into a semiconductor substrate, which is the so-called ion implantation process. In other words, in the manufacturing method according to the first embodiment, an ion implanter generates an ion beam and irradiates the ion beam onto a semiconductor substrate (for example, a silicon wafer), so as to form an impurity diffused layer in the semiconductor substrate.

In the ion implanter that accelerates an ion beam with relatively high energy and then decelerates the ion beam, when the ion beam is decelerated, ion collision occurs such that some ions are neutralized. Neutral particles generated by the ion neutralization cannot be controlled in an electric field. Therefore, the neutral particles are implanted into a semiconductor substrate without being decelerated by a decelerator.

For this reason, in the manufacturing method according to the first embodiment, an ion-beam deceleration ratio is controlled such that an amount of ions to be neutralized is controlled. In other words, separately from an impurity profile that is formed in the semiconductor substrate by ions, the ion-beam deceleration ratio is controlled such that a desired impurity profile due to neutral particles is formed in the semiconductor substrate.

For example, in the ion implanter illustrated in FIG. 1A, the acceleration energy of an ion beam accelerated and extracted by an extraction electrode is denoted by E2 (keV), and the acceleration energy of the ion beam that is decelerated by the decelerator is denoted by E1 (keV). In this case, as the deceleration ratio (=E2/(E2−E1)) increases, an amount of ions to be neutralized increases.

The acceleration energy E2 (keV) changes according to a voltage value of a voltage (hereinafter, referred to as an extraction voltage) that is applied to the extraction electrode. Also, the acceleration energy E1 (keV) changes according to a voltage value of a voltage (hereinafter, referred to as a deceleration voltage) that is applied to the decelerator.

As described above, in the manufacturing method according to the first embodiment, the extraction voltage and the deceleration voltage are controlled such that neutralization of ions to be included in an ion beam is controlled, whereby an amount of neutral particles to be included in the ion beam is adjusted.

Since the neutral particles are implanted into the semiconductor substrate without being decelerated by the decelerator, in the manufacturing method according to the first embodiment, the extraction voltage is controlled such that energy of the neutral particles to be implanted into the semiconductor substrate is adjusted.

If the extraction voltage and the deceleration voltage are controlled as described above, it becomes possible to form a desired impurity profile XPb due to neutral particles in addition to the an impurity profile XPa due to ions, as illustrated in FIG. 1B, in a semiconductor substrate by one ion implantation process. Since ions can be decelerated by the decelerator but neutral particles cannot be decelerated by the decelerator, the implantation energy of the neutral particles into a semiconductor substrate is higher than the implantation energy of the ions. For this reason, the impurity profile XPb is formed in a region deeper than the position of the formation of the impurity profile XPa.

As described above, in the manufacturing method according to the first embodiment, the impurity profile XPa and the impurity profile XPb are formed by one ion implantation process. Therefore, it is possible to reduce the number of ion implantation processes, as compared to a case of forming the impurity profile XPa and the impurity profile XPb by separate ion implantation processes. In other words, in the ion implantation process according to the first embodiment, it is possible to achieve a very noticeable effect in which it is possible to improve throughput.

The impurity profile XPa corresponds to a first impurity profile, and the impurity profile XPb corresponds to a second impurity profile. The extraction voltage corresponds to a first voltage, and the deceleration voltage corresponds to a second voltage.

Here, taking an ion implantation process in manufacturing a semiconductor device including a p-type MOSFET for example, the manufacturing method according to the first embodiment will be described in more detail.

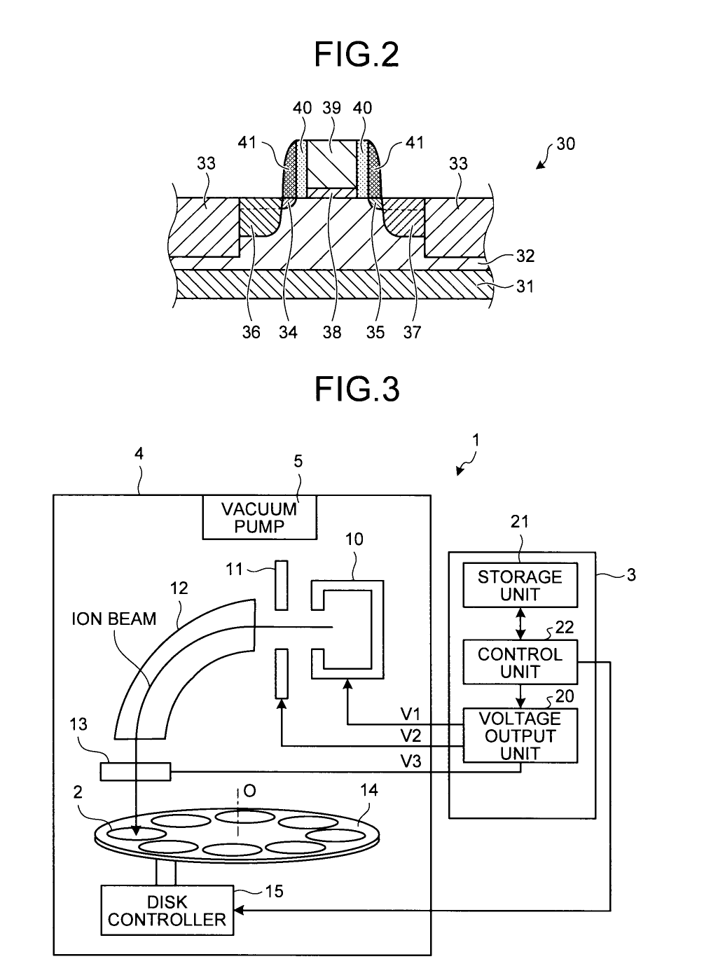

First, referring to FIG. 2, the configuration of a p-type MOSFET will be described. FIG. 2 is a diagram illustrating the configuration of a semiconductor device according to the first embodiment.

As illustrated in FIG. 2, in the semiconductor device 30 according to the first embodiment, an n-type well region 32 is formed in a p-type semiconductor substrate 31. The semiconductor substrate 31 is a monocrystal silicon substrate for instance.

In the n-type well region 32, element isolation regions 33 are selectively formed. Further, in the n-type well region 32, a source extension region 34, a drain extension region 35, a source region 36, and a drain region 37 are formed. Furthermore, on the n-type well region 32, a gate electrode 39 is formed with a gate insulating film 38 interposed therebetween.

On both side surfaces of the gate insulating film 38 and the gate electrode 39, a pair of sidewall spacers 40 composed of silicon oxide films is formed so as to sandwich the gate insulating film 38 and the gate electrode 39 therebetween. Further, a pair of sidewall spacers 41 composed of silicon nitride films is formed so as to sandwich the outer sides of the pair of sidewall spacers 40 facing each other.

Here, the source region 36 and the drain region 37 are formed according to the first impurity profile XP1 and the second impurity profile XP2, and the impurity profiles XP1 and XP2 are formed by one time of ion implantation. According to the first impurity profile XP1 and the second impurity profile XP2, it is possible to form an impurity diffused layer which has shallow p-n junction, low parasitic resistance, and low leakage current, for instance.

In order to form the source region 36 and the drain region 37, an ion implanter illustrated in FIG. 3 may be used. FIG. 3 is a diagram illustrating the configuration of an ion implanter for implementing the manufacturing method according to the first embodiment.

As illustrated in FIG. 3, an ion implanter 1 that is used for the manufacturing method according to the first embodiment includes an ion source 10, an extraction electrode 11, a mass spectrometer 12, a decelerator 13, a rotary disk 14, and a disk controller 15. These are provided in a vacuum chamber 4 having a vacuum pump 5, and are controlled by a controller 3.

The ion source 10 has an arc chamber, and BF₃ gas is introduced into the arc chamber. The BF₃ gas in the arc chamber is decomposed by arc discharge, such that ions mainly including boron ions (B+) are generated in the arc chamber. To the arc chamber, a voltage V1 is applied.

To the extraction electrode 11, an extraction voltage V2 is applied. The extraction voltage V2 is a voltage lower than the voltage V1 that is applied to the arc chamber, and thus an electric field is generated between the arc chamber and the extraction electrode 11. This electric field accelerates the ions including the boron ions, such that the ions are extracted as an ion beam from the ion source 10. This ion beam is introduced into the mass spectrometer 12.

The mass spectrometer 12 separates the boron ions having a predetermined mass, from the ion beam extracted from the ion source 10. The ion beam from which the boron ions have been extracted by the mass spectrometer 12 is introduced into the decelerator 13.

To the decelerator 13, a deceleration voltage V3 which is a voltage higher than the extraction voltage V2 is applied. Therefore, the decelerator 13 decelerates the ion beam output from the mass spectrometer 12.

The disk controller 15 controls movement of the rotary disk 14 in a vertical direction to the direction of a rotation axis O. In other words, the ion implanter 1 performs mechanical scanning type ion implantation in which the rotary disk 14 mechanically moves to the front side, the rear side, the left side, and the right side in FIG. 3 and ion implantation is performed. Here, an example in which 8 semiconductor substrates 2 (for example, silicon wafers) have been mounted on the rotary disk 14 is illustrated. However, the number of semiconductor substrates 2 to be mounted on the rotary disk 14 is not limited to 8.

The controller 3 includes a voltage output unit 20, a storage unit 21, and a control unit 22. The voltage output unit 20 outputs the voltage V1 to be applied to the arc chamber of the ion source 10, the extraction voltage V2 to be applied to the extraction electrode 11, and the deceleration voltage V3 to be applied to the decelerator 13, on the basis of the control of the control unit 22.

The storage unit 21 stores various information regarding ion implantation. For example, the storage unit 21 stores information on an ion implantation condition including information on the voltages V1 to V3 and information on a degree of vacuum inside the vacuum chamber 4. For example, this information on the ion implantation condition is input by an input unit (not illustrated) of the controller 3, and is stored in the storage unit 21.

The control unit 22 controls the magnitudes of the voltages V1 to V3 to be output from the voltage output unit 20, the degree of vacuum inside the vacuum chamber 4, and the disk controller 15, on the basis of the information on the ion implantation condition stored in the storage unit 21.

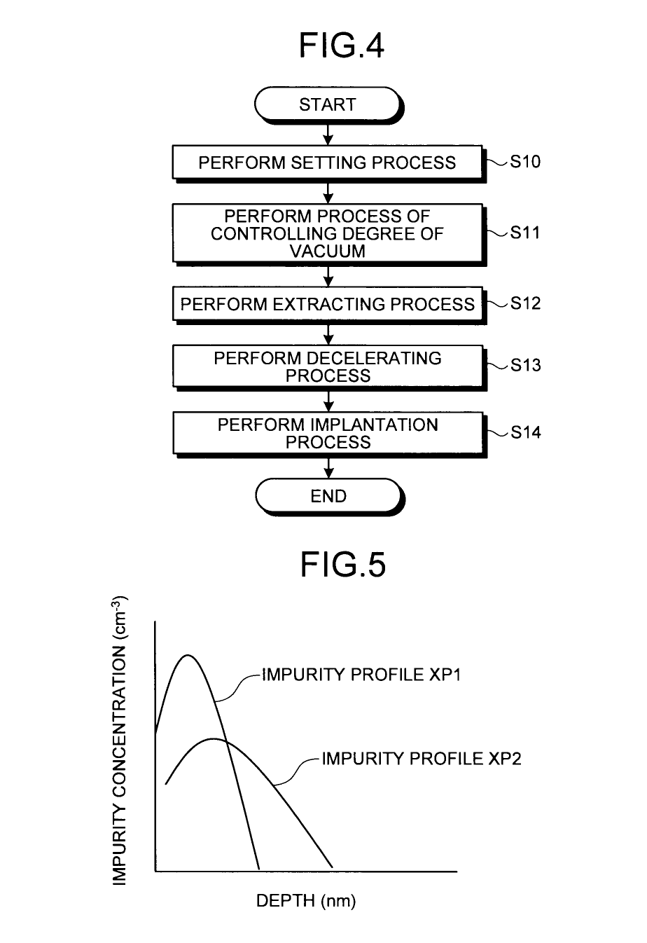

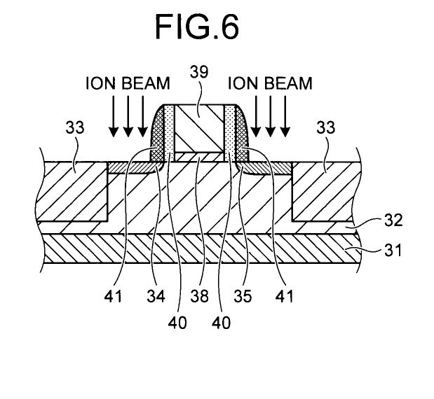

According to the ion implanter 1 configured as described above, the source region 36 and the drain region 37 illustrated in FIG. 2 are formed as follow. FIG. 4 is a drawing illustrating the procedure of the manufacturing method according to the first embodiment, FIG. 5 is a drawing illustrating impurity profiles that are formed in the semiconductor device 30 according to the first embodiment, and FIG. 6 is a cross-sectional view for describing a process of the method of manufacturing the semiconductor device 30 according to the first embodiment.

As illustrated in FIG. 4, first, in STEP S10, a setting process is performed. In this setting process, the ion implantation condition for forming the first impurity profile XP1 due to the boron ions B+ and the second impurity profile XP2 due to neutral particles of boron is set.

For example, the ion implantation condition are input from the input unit (not illustrated) of the controller 3, and information on the ion implantation condition is stored in the storage unit 21 by the control unit 22, thereby performing the setting of the ion implantation condition. Here, the ion implantation condition is set such that the first impurity profile XP1 and the second impurity profile XP2 are formed in the semiconductor substrate 2.

As illustrated in FIG. 5, the first impurity profile XP1 is an impurity profile which is formed by ion-implanting the boron ions B+ with the acceleration energy of 1 keV and a dose amount of 3×10¹⁵ cm⁻². The second impurity profile XP2 is an impurity profile which is formed by ion-implanting the neutral particles of boron with the acceleration energy of 3 keV and a dose amount of 4×10¹⁴ cm⁻².

Next, in STEP S11, a process of controlling the degree of vacuum is performed. In this process of controlling the degree of vacuum, the control unit 22 reads the ion implantation condition from the storage unit 21, and controls the vacuum pump 5 on the basis of the read ion implantation condition. Therefore, the degree of vacuum inside the vacuum chamber 4 is controlled.

Next, in STEP S12, an extracting process of extracting the ion beam from the ion source 10 is performed. In this extracting process, the control unit 22 reads the ion implantation condition from the storage unit 21, and controls the voltage output unit 20 on the basis of the read ion implantation condition. Therefore, the voltage V1 is applied from the voltage output unit 20 to the arc chamber of the ion source 10, and the extraction voltage V2 is applied from the voltage output unit 20 to the extraction electrode 11, such that the ion beam is extracted from the ion source 10.

Next, in STEP S13, a decelerating process of decelerating the ion beam extracted from the ion source 10 is performed. In this decelerating process, the control unit 22 reads the ion implantation condition from the storage unit 21, and controls the voltage output unit 20 on the basis of the read ion implantation condition. Therefore, the deceleration voltage V3 is applied to the decelerator 13 such that the ion beam is decelerated.

The ion beam decelerated by the decelerator 13 is irradiated onto the semiconductor substrate 31 having the n-type well region 32, as illustrated in FIG. 6. Therefore, in STEP S14, an implantation process is performed. In this implantation process, as described above, the extraction voltage V2 and the deceleration voltage V3 have been set. Therefore, the first impurity profile XP1 and the second impurity profile XP2 illustrated in FIG. 5 are formed in the n-type well region 32, and the source region 36 and the drain region 37 of the p-type MOSFET are formed as illustrated in FIG. 2.

As described above, in the manufacturing method according to the first embodiment, not only the impurity profile XP1 due to the boron ions but also the desired impurity profile XP2 due to the neutral particles of boron are formed in the semiconductor substrate 31 by one ion implantation process. In other words, two impurity profiles may be formed in the semiconductor substrate 31 by one time of ion implantation. As a result, the throughput may be improved.

The above-mentioned extracting process, decelerating process, and implantation process are performed in the vacuum chamber 4 in a vacuum environment. The ion neutralization also changes according to the degree of vacuum inside the vacuum chamber 4. In the vacuum environment, if the degree of vacuum inside the vacuum chamber 4 is reduced, the probability of collision with particles increased in proportion to the reduction increases. For example, if the degree of vacuum inside the vacuum chamber 4 is reduced from 1×10⁻³ Pa to 1×10⁻² Pa, that is, to 1 in 10, the neutralized ions increase ten times.

For this reason, in the manufacturing method according to the first embodiment, the degree of vacuum inside the vacuum chamber 4 is controlled by the process of adjusting the degree of vacuum, such that the concentration of the neutralized ions is controlled. In other words, the amount of neutral particles to be included in the ion beam is controlled. Therefore, the first impurity profile XP1 and the second impurity profile XP2 may be formed more accurately.

### Second Embodiment

Next, a manufacturing method according to a second embodiment will be described. The manufacturing method according to the second embodiment forms an impurity diffused layer having less residual defects as compared to the manufacturing method according to the first embodiment. Similarly to the manufacturing method according to the first embodiment, in the manufacturing method according to the second embodiment, the ion implanter 1 may be used. Now, similarly to the first embodiment, the manufacturing method according to the second embodiment will be described taking the case of manufacturing the semiconductor device 30 (see FIG. 2) having the p-type MOSFET for example.

In the manufacturing method according to the second embodiment, similarly to the manufacturing method according to the first embodiment, the ion implantation condition including the information on the voltages V1 to V3 and the information on the degree of vacuum inside the vacuum chamber 4 is set. Next, in the manufacturing method according to the second embodiment, not only an impurity profile XP3 due to boron ions B+ but also an impurity profile XP4 due to neutral particles of boron are formed in a substrate by one ion implantation process based on the ion implantation condition.

Then, the impurity profile XP4 is appropriately set with respect to the impurity profile XP3, such that a source region 36 and a drain region 37 having less residual defects after an annealing treatment are formed. Therefore, it becomes possible to improve the performance and performance stability of the p-type MOSFET while improving the throughput.

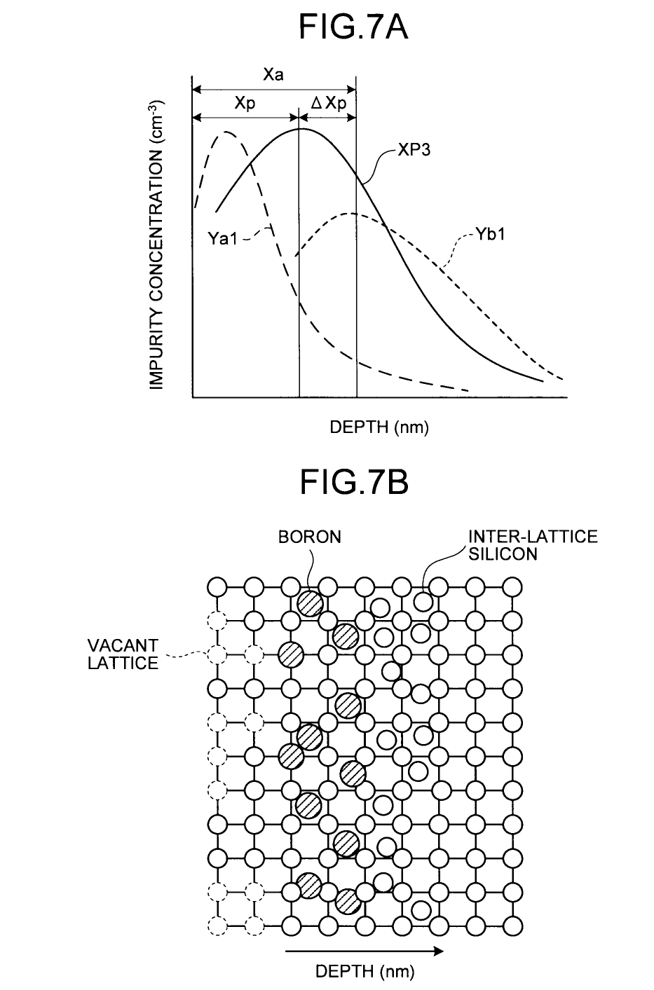

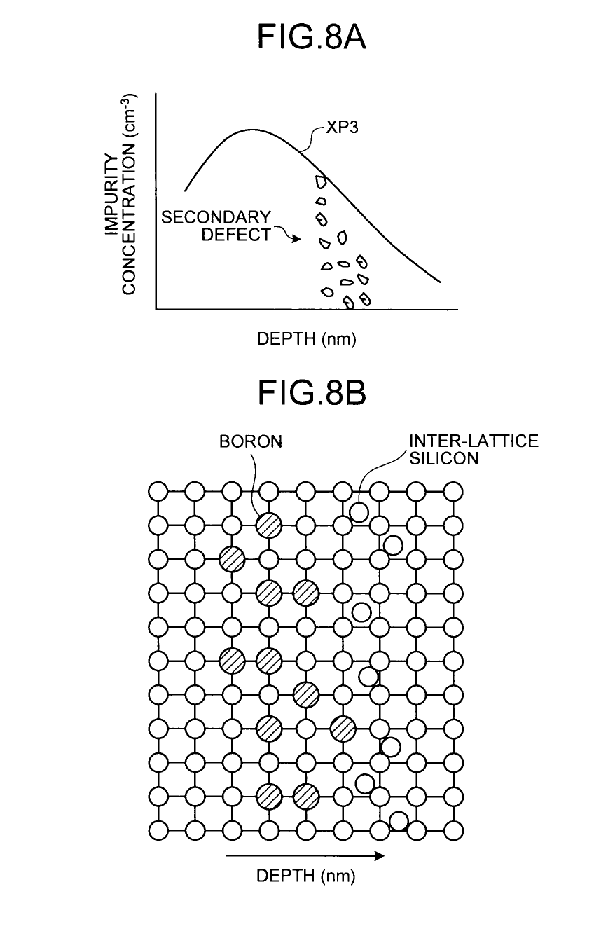

Hereinafter, the manufacturing method according to the second embodiment will be described in detail. First, the residual defects will be described. FIGS. 7A, 7B, 8A, and 8B are explanatory views of occurrence of the residual defects.

A case of forming the impurity profile XP3 as illustrated in FIG. 7A by ion implantation is considered. In this case, as illustrated in FIG. 7A, vacant lattices Ya1 having a peak concentration (density) at a position shallower than a peak concentration position of the impurity profile XP3 are formed, and inter-lattice silicon Yb1 having a peak concentration (density) at a position deeper than the peak concentration position of the impurity profile XP3 is disposed.

FIG. 7B simply and schematically illustrates the internal state of the semiconductor substrate 31 illustrated in FIG. 7A. In case of performing the annealing treatment in that state, as illustrated in FIGS. 8A and 8B, secondary defects are formed in the semiconductor substrate 31 by the inter-lattice silicon Yb1. The position where the secondary defects are formed is the vicinity of the peak concentration position Xa (=Xp+ΔXp) (see FIG. 7A) of the inter-lattice silicon Yb1, and the secondary defects may increase the leakage current.

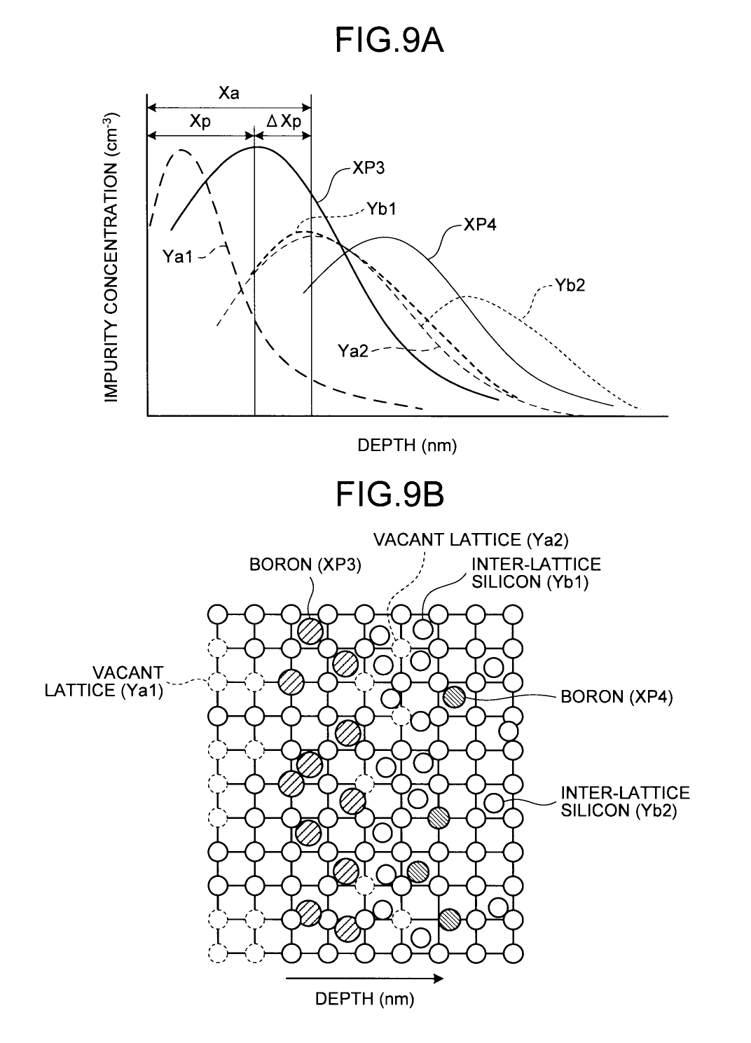

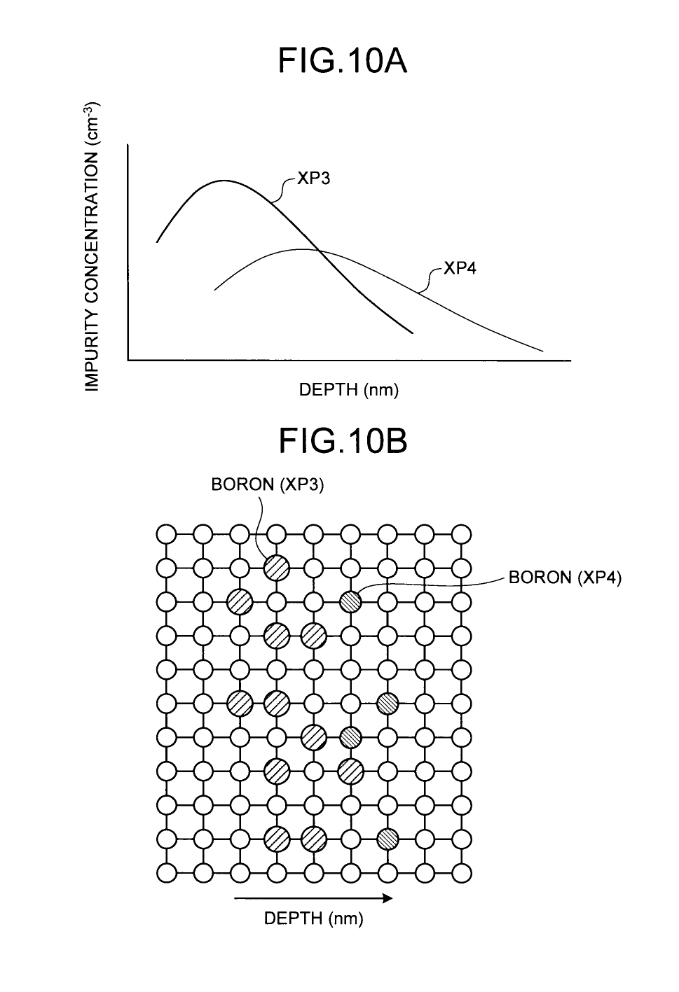

For this reason, in the manufacturing method according to the second embodiment, after the impurity profile XP4 according to the concentration distribution of the inter-lattice silicon Yb1 is formed, the annealing treatment is performed on the substrate having the impurity profile formed therein. FIGS. 9A, 9B, 10A, and 10B are explanatory views of the manufacturing method according to the second embodiment.

In the manufacturing method according to the second embodiment, as illustrated in FIG. 9A, not only the impurity profile XP3 but also the impurity profile XP4 are formed in the substrate at once by the ion implanter 1. The impurity profile XP4 is an impurity profile in which the distribution of vacant lattices Ya2 formed according to the formation of the impurity profile XP4 coincides approximately with the distribution of the inter-lattice silicon Yb1 generated by the formation of the impurity profile XP3. In other words, the impurity profile XP4 is a profile in which the peak concentration and position of the vacant lattices Ya2 formed according to the formation of the impurity profile XP4 coincides approximately with those of the inter-lattice silicon Yb1.

FIG. 9B simply and schematically illustrates the internal state of the semiconductor substrate 31 illustrated in FIG. 9A. The vacant lattices Ya2 and inter-lattice silicon Yb2 are formed when the impurity profile XP4 is formed.

In a case of performing the annealing treatment in that state, as illustrated in FIGS. 10A and 10B, the secondary defects that are formed in the substrate are reduced. This is because, after annealing, the inter-lattice silicon Yb1 is rearranged at the vacant lattices Ya2 and the concentration of the inter-lattice silicon Yb2 is low, so that formation of secondary defects is difficult.

As described above, in the second embodiment, the two impurity profiles XP3 and XP4 are formed at once by the ion implanter 1. Therefore, it is possible to improve the throughput, and to reduce the secondary defects that are formed in the semiconductor substrate 31, thereby suppressing the increase in the leakage current.

It is preferable that the distribution of the inter-lattice silicon Yb1 coincides approximately with the distribution of the vacant lattices Ya2; however, the present invention is not necessarily limited thereto. That is, if the impurity profile XP4 is formed such that the distribution of the inter-lattice silicon Yb1 that is generated according to the formation of the impurity profile XP3 efficiently overlaps the distribution of the vacant lattices Ya2 that are formed according to the formation of the impurity profile XP4, it is possible to reduce the secondary defects.

In the second embodiment, the two impurity profiles XP3 and XP4 are formed at once by the ion implanter 1; however, the present invention is not limited thereto. For example, an ion implantation process for the impurity profile XP3 (hereinafter, referred to as a first ion implantation process) and an ion implantation process for the impurity profile XP4 (hereinafter, referred to as a second ion implantation process) may be performed separately.

The conductivity type of a material that is implanted by the first ion implantation process may be opposite to the conductivity type of a material that is implanted by the second ion implantation process. For example, the impurity profile XP3 may be formed with an n-type material and the impurity profile XP4 may be formed with a p-type material, or vice versa. The implanted material may be conductive or nonconductive.

### Third Embodiment

Next, a manufacturing method according to a third embodiment will be described. The manufacturing method according to the third embodiment efficiently forms three or more impurity profiles having different peak positions in a substrate. Similarly to the manufacturing methods according to the first and second embodiments, in the manufacturing method according to the third embodiment, the ion implanter 1 may be used.

In the manufacturing method according to the third embodiment, three or more impurity profiles having different depths (peak concentration positions) are formed to form a thick impurity layer. Here, 11 impurity profiles having different depths are formed as an example; however, the present invention is not limited thereto.

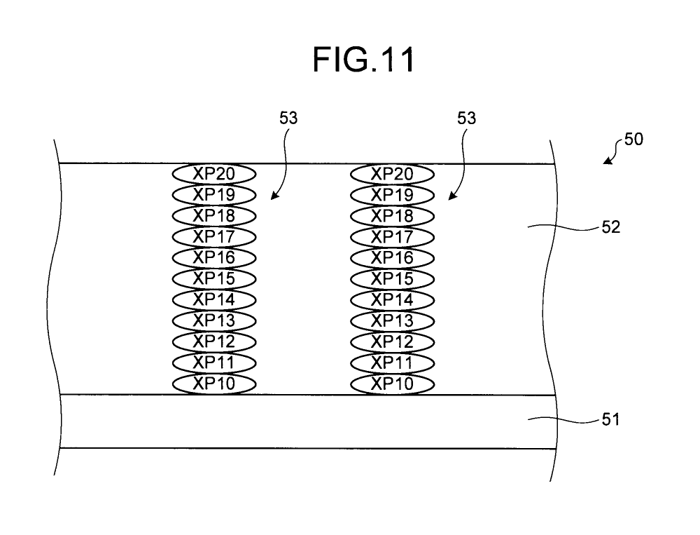

Specifically, in the manufacturing method according to the third embodiment, as illustrated in FIG. 11, pixel isolation regions 53 of a solid-state image sensor 50 which is an example of a semiconductor device are formed. In other words, impurity profiles XP10 to XP20 having different depths are formed in an n-type epitaxial layer 52 formed in a silicon substrate 51. FIG. 11 is a cross-sectional view of a semiconductor device according to the third embodiment.

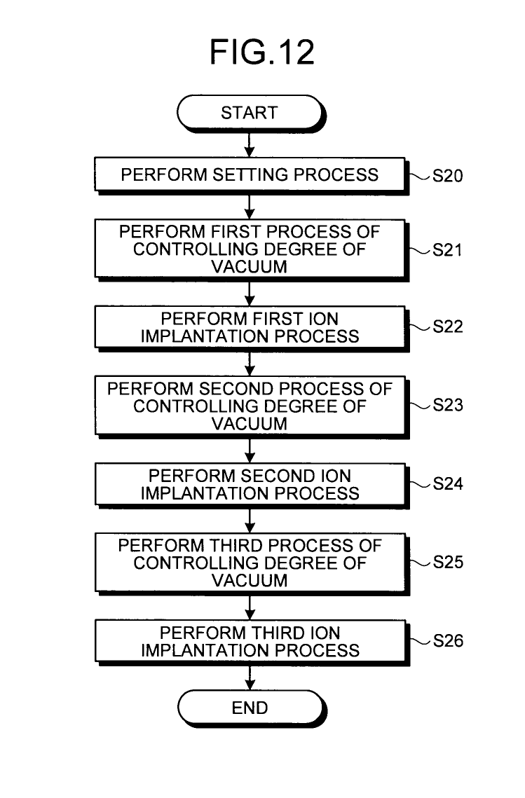

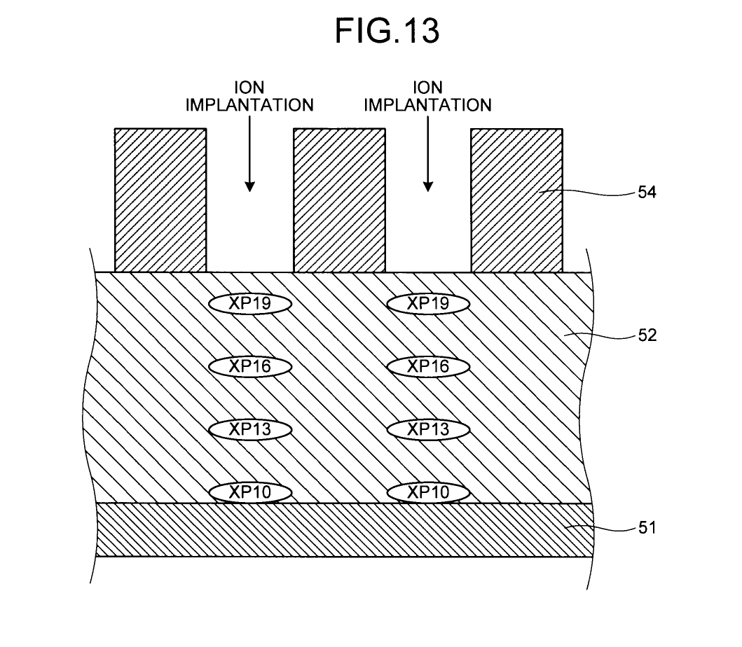

Hereinafter, the method of manufacturing the semiconductor device illustrated in FIG. 11 will be described in detail with reference to FIGS. 12 to 15. FIG. 12 is a diagram illustrating the procedure of the manufacturing method according to the third embodiment, and FIGS. 13 to 15 are cross-sectional views illustrating processes of the manufacturing method according to the third embodiment. In the third embodiment, it is assumed that the ion source 10 of the ion implanter 1 generates monovalent, divalent, and trivalent boron ions B+, B++, and B+++.

As illustrated in FIG. 12, first, in STEP S20, a setting process is performed. In this setting process, first to third ion implantation conditions including the information on the voltages V1 to V3 and the information on the degree of vacuum inside the vacuum chamber 4 are set.

Next, in STEP S21, a first process of controlling the degree of vacuum is performed. In this first process of controlling the degree of vacuum, the control unit 22 reads the first ion implantation condition from the storage unit 21, and controls the vacuum pump 5 on the basis of the first ion implantation condition. Therefore, the degree of vacuum inside the vacuum chamber 4 is controlled.

Next, in STEP S22, a first ion implantation process is performed. In this first ion implantation process, the control unit 22 reads the first ion implantation condition from the storage unit 21, and controls the voltage output unit 20 on the basis of the first ion implantation condition. Therefore, the voltage V1 is applied from the voltage output unit 20 to the arc chamber of the ion source 10, and the extraction voltage V2 is applied from the voltage output unit 20 to the extraction electrode 11, so that the ion beam is extracted from the ion source 10. Further, the deceleration voltage V3 is applied from the voltage output unit 20 to the decelerator 13, so that the ion beam extracted from the ion source 10 decelerates.

The ion beam decelerated by the decelerator 13 is irradiated onto a region without a mask 54 formed thereon, of the n-type epitaxial layer 52 formed on the silicon substrate 51. Here, as described above, the ion source 10 generates the monovalent, divalent, and trivalent boron ions B+, B++, and B+++. On the basis of the preset first ion implantation condition, the extraction voltage V2 and the deceleration voltage V3 are controlled, and the degree of vacuum inside the vacuum chamber 4 is controlled.

Therefore, neutralization of the ion beam occurs such that four impurity profiles XP10, XP13, XP16, and XP19 due to the boron ions B+, B++, and B+++ and neutral particles of boron are formed in the n-type epitaxial layer 52, as illustrated in FIG. 13. The depths at which the four impurity profiles are to be formed can be appropriately changed by adjusting the first ion implantation condition.

Next, in STEP S23, a second process of controlling the degree of vacuum is performed. In this second process of controlling the degree of vacuum, the control unit 22 reads the second ion implantation condition from the storage unit 21, and controls the vacuum pump 5 on the basis of the second ion implantation condition. Therefore, the degree of vacuum inside the vacuum chamber 4 is controlled.

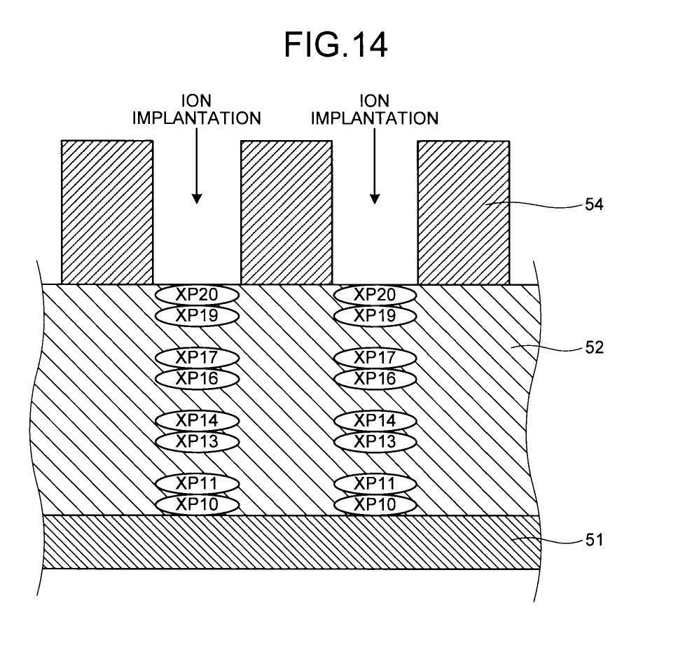

Next, in STEP S24, a second ion implantation process is performed. In this second ion implantation process, the control unit 22 reads the second ion implantation condition from the storage unit 21, and controls the voltage output unit 20 on the basis of the second ion implantation condition. Therefore, as illustrated in FIG. 14, four impurity profiles XP11, XP14, XP17, and XP20 due to the boron ions B+, B++, and B+++ and the neutral particles of boron are formed in the n-type epitaxial layer 52. The depths at which the four impurity profiles are to be formed can be appropriately changed by adjusting the second ion implantation condition.

Next, in STEP S25, a third process of controlling the degree of vacuum is performed. In this third process of controlling the degree of vacuum, the control unit 22 reads the third ion implantation condition from the storage unit 21, and controls the vacuum pump 5 on the basis of the third ion implantation condition. Therefore, the degree of vacuum inside the vacuum chamber 4 is controlled.

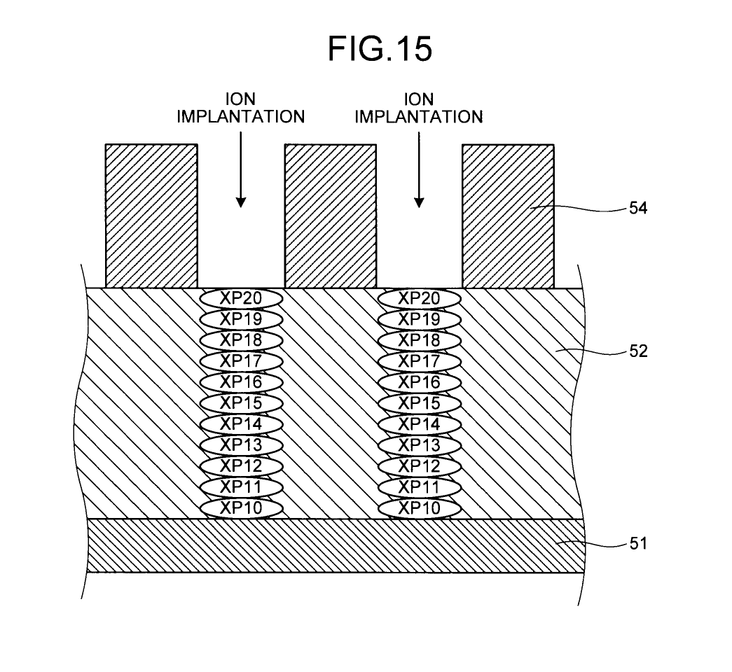

Next, in STEP S26, a third ion implantation process is performed. In this third ion implantation process, the control unit 22 reads the third ion implantation condition from the storage unit 21, and controls the voltage output unit 20 on the basis of the third ion implantation condition. In the third ion implantation condition, the extraction voltage V2, the deceleration voltage V3, the degree of vacuum inside the vacuum chamber 4, and the like are set such that neutralization of the ion beam is suppressed. Therefore, as illustrated in FIG. 15, three impurity profiles XP12, XP15, and XP18 due to the boron ions B+, B++, and B+++ are formed in the n-type epitaxial layer 52. The depths at which the three impurity profiles are to be formed can be appropriately changed by adjusting the third ion implantation condition.

As described above, in the manufacturing method according to the third embodiment, the monovalent, divalent, and trivalent ions are generated in the ion source 10, and the extraction voltage V2, the deceleration voltage V3, the degree of vacuum inside the vacuum chamber 4, and the like are controlled. Therefore, it becomes possible to form the impurity profiles XP10 to XP20 by three ion implantation processes.

In the above-mentioned example, the ion source 10 generates the monovalent, divalent, and trivalent boron ions B+, B++, and B+++; however, the present invention is not limited thereto. For example, the ion source 10 may generate the monovalent and divalent boron ions B+ and B++, so that three impurity profiles are formed.

Alternatively, for example, the ion source 10 may mainly generate the monovalent boron ions B+ such that two impurity profiles are formed by the boron ions and the neutral particles of boron. In this case, in order to form the pixel isolation regions 53 illustrated in FIG. 11, it is possible to form the impurity profiles XP10 to XP20 by six ion implantation processes.

As described above, in the manufacturing method according to the third embodiment, it is possible to tremendously improve the throughput as compared to a case of performing an ion implantation process for each of the impurity profiles XP10 to XP20. In other words, in the case of perform an ion implantation process for each of the impurity profiles XP10 to XP20, the extraction voltage V2 and the deceleration voltage V3 are changed for each implantation depth, and thus time is required to start up the ion beam for each condition. Meanwhile, in the manufacturing method according to the third embodiment, since implantation to a plurality of depths is performed on one condition, it is possible to form a plurality of impurity profiles at once. Therefore, for example, as described above, in a case of forming the pixel isolation regions 53 to separate the epitaxial layer 52 having a thickness of several μm, it becomes to tremendously improve the throughput.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the above-mentioned embodiments, as ions that are generated in the ion source, the boron ions have been exemplified; however, the present invention is not limited thereto. Further, as the semiconductor device, the semiconductor device 30 having the p-type MOSFET and the solid-state image sensor 50 have been exemplified; however, the present invention is not limited thereto.

What is claimed is:

1. A method of manufacturing a semiconductor device comprising:
applying a first voltage to an electrode configured to extract an ion beam from an ion source, thereby extracting an ion beam from the ion source;
applying a second voltage to a decelerator through which the extracted ion beam is to pass, thereby reducing acceleration energy of the ion beam;
irradiating the ion beam having passed through the decelerator onto a substrate, thereby producing a first impurity profile based on ions included in the ion beam and a second impurity profile based on neutral particles included in the ion beam, in the substrate; and
setting the first voltage and the second voltage in accordance with the second impurity profile.

2. The method of manufacturing a semiconductor device according to claim 1, wherein
the extraction of the ion beam by the electrode, the reduction of the acceleration energy by the decelerator, and the formation of the impurity profiles are performed in a vacuum environment, and
a degree of vacuum of the vacuum environment is set in accordance with the second impurity profile.

3. The method of manufacturing a semiconductor device according to claim 1, wherein the first voltage and the second voltage are set such that a distribution of inter-lattice silicon generated according to the formation of the first impurity profile overlaps a distribution of vacant lattices generated according to the formation of the second impurity profile.

4. The method of manufacturing a semiconductor device according to claim 1, wherein
the ion source generates ions of a monovalent ion to an n-valence (n≧2) ion, and
the first impurity profile is formed by an impurity profile of the ions having each valence.

5. The method of manufacturing a semiconductor device according to claim 1, wherein the extraction of the ion beam by the electrode, the reduction of the acceleration energy by the decelerator, and the formation of the impurity profiles are repeatedly performed while changing the first voltage and the second voltage.

6. An ion implanter comprising:
an ion source;
an electrode that extracts an ion beam from the ion source;
a decelerator that reduces acceleration energy of the ion beam having been extracted from the ion source by the electrode;
a voltage output unit that applies a first voltage to the electrode so that the ion beam is extracted from the ion source, and applies a second voltage to the decelerator so that the acceleration energy of the ion beam is reduced; and
a control unit that controls the voltage output unit such that the ion beam having passed through the decelerator is irradiated onto a substrate, thereby forming a first impurity profile based on ions included in the ion beam and a second impurity profile based on neutral particles included in the ion beam, in the substrate,
wherein the control unit causes the voltage output unit to apply the first voltage and the second voltage to the electrode and the decelerator, respectively according to the second impurity profile.

7. The ion implanter according to claim 6, further comprising a vacuum chamber that accommodates the ion source, the electrode, and the decelerator,
wherein the control unit sets a degree of vacuum of the vacuum chamber to a degree of vacuum according to the second impurity profile.

8. The ion implanter according to claim 6, wherein the control unit causes the voltage output unit to apply the first voltage and the second voltage to the electrode and the decelerator, respectively such that a distribution of inter-lattice silicon generated according to the formation of the first impurity profile overlaps a distribution of vacant lattices generated according to the formation of the second impurity profile.

9. The ion implanter according to claim 6, wherein
the ion source generates ions of a monovalent ion to an n-valence (n≧2) ion, and
the first impurity profile is formed by an impurity profile of the ions having each valence.

10. The ion implanter according to claim 6, wherein the control unit controls the voltage output unit such that the first voltage and the second voltage change, thereby forming a plurality of sets of the first impurity profile and the second impurity profile.
